(19) United States
(12) Patent Application Publication
(10) Pub. No.: US 2007/0128743 A1
(43) Pub. Date: Jun. 7, 2007

(54) Process of producing group III nitride based reflectors

(75) Inventors: Gensheng Huang, Hsinchu City (TW); Hsin-Hung Yao, Banciao City (TW); Hao-Chung Kuo, Hsinchu City (TW); Shing-Chung Wang, Hsinchu City (TW)

Correspondence Address: BUCKNAM AND ARCHER, 1077 NORTHERN BOULEVARD, ROSLYN, NY, 11576, US

(73) Assignee: National Chiao Tung University, Hsinchu (TW)

(21) Appl. No.: 11/328,022

(22) Filed: Jan. 9, 2006

(30) Foreign Application Priority Data
Dec. 5, 2005 (TW) 094142756

(51) Int. Cl. H01L 21/00; H01L 33/00

(52) U.S. Cl. 438/21; 257/79

(57) ABSTRACT

To solve the existing problems in distributed Bragg reflectors (DBR) used in the prior art, the present invention provides a fabrication method of group III nitride based distributed Bragg reflectors (DBR) for vertical cavity surface emitting lasers (VCSELs), which suppresses the generation of cracks, and a distributed Bragg reflector with high reflectivity, broad stopband, and adaptability to optical devices such as vertical cavity surface emitting lasers, micro-cavity light emitting diodes, resonance cavity light emitting diodes and photodetectors.

### FIELD OF THE INVENTION

The present invention is directed to the process for fabricating group III nitride based distributed Bragg reflectors without cracks, and with high reflectivity and broad stopband. In particular, the present invention is directed to the process for fabricating group III nitride based distributed Bragg reflector, which are crack-free and with high reflectivity and broad stopband. The group III nitride based distributed Bragg reflector will be widely applied in optical devices such as vertical cavity surface emitting lasers, micro-cavity light emitting diodes, resonance cavity light emitting diodes and photodetectors.

### DESCRIPTION OF THE RELATED PRIOR ART

In recent years, vertical cavity surface emitting lasers (VCSELs) have been popular due to the ability to generate various laser wavelengths at, e.g., 1550 nm, 1310 nm, 850 nm, 670 nm, etc., excellent photoelectric properties, and availability from a variety of materials.

For VCSELs made of various materials, vertical cavity surface emitting lasers, micro-cavity light emitting diodes (MCLED) and resonance cavity light emitting diodes (RCLED) with distributed Bragg reflectors have been widely applied in full color display, photolithography, super high density optical memory and bright white light source, due to the excellent photoelectric properties. For example, the group III nitride based VCSELs (III-N-VCSELs) possesses many advantages properties over the edge emitting lasers including circular beam shape, light emission in vertical direction, low threshold current, single longitude-mode and formation of two-dimensional arrays; group III nitride based resonance cavity light emitting diodes (III-N-RCLED) have been widely applied in plastic optical fibers; and GaN/Al(Ga)N, AlN/Ga(Al)N multilayers have been used as high reflective mirrors on the bottom side.

In general, VCSELs are grown on substrates, e.g., insulating sapphire monocrystals, various oxides crystals, silicon carbide monocrystals, and group III-V compound semiconductor monocrystals, by conducting layer deposition with metalorganic chemical vapor phase deposition (MOCVD), molecular beam epitaxy (MBE) or hydride vapor phase epitaxy (HVPE) or hot wall epitaxy (HWE).

Typical VCSELs comprise semiconductive n type, p type and active layers, distributed Bragg reflectors (DBR), current restriction structure, substrates and connects. Active layers are generally made of GaN based compounds having formula of AlₓIn_{y}Ga_{1-x-y}N (0≦x<1, 0≦y<1, x+y<1). Normally for blue VCSEL, InGaN is used with particular compositions and light emitting wavelengths, which is sandwiched by larger band gap materials such as GaN. They possess the bi-heterogeneous structure or single quantum well structure or multiple quantum wells effect. However, GaN based light emission devices with active layers of multiple quantum wells are difficult to achieve desire output power with high driving voltage.

Many proposals have been produced to solve these issues arisen by VCSELs. For example, in Reference 1, a set of GaN/GaAlN superlattices was grown prior to the growth of reflectors to release strain and to obtain GaN/GaAlN reflectors without cracks. A large number of pairs of reflectors are needed to achieve high reflectivity with narrow stopband, due to the small difference of refractive index between GaAlN and GaN materials. However, GaN based materials was grown on sapphire. There is large lattice mismatch between GaN and sapphire, so there is a large number of dislocations and defects in GaN epilayer. They affect the quality of epilayers and cause the light loss to reduce the reflectivity. For example, it is very difficult to grow reflectors with more than 30 layers directly in Reference 1.

Further, in Reference 2, AlN/GaN distributed Bragg reflectors with high reflectivity and broad stopband were grown by MBE. Though the process effectively decreases the number of pairs of reflectors to around 20 to 25, it is difficult to obtain high quality of reflectors due to the presence of cracks on surface, caused by the lattice mismatches between AlN and GaN.

Mentioned as above, distributed Bragg reflectors have not reached to the device requirements of high quality, high reflectivity and broad stop band. In view of the realizaton in vertical cavity surface emitting lasers, a proposal will be produced to suppress the generation of crack to achieve distributed Bragg reflector with high reflectivity and broad stopband,

[Reference 1] Nakada, H. Ishikawa, T. Egawa, T. Jimbo, “Suppression of Crack Generation in GaN/AlGaN Distributed Bragg Reflector on Sapphire by the of GaN/AlGaN Superlattices Grown by Metal-Organic Chemical Vapor Deposition,” Jpn. J. Appl. Phys. Pt. 2 42(2003) L144.

[Reference 2] H. M. Ng, T. D. Moustakas. S. N, G. Chu, “High reflectivity and broad bandwidth AIN/GaN distributed Bragg reflectors grown by molecular-beam epitaxy,” Appl. Phys. Lett. 76 (2000) 2818.

### SUMMARY OF THE INVENTION

In order to solve the existing problems in DBRs as mentioned, the object of the present invention is to provide a fabrication method of DBRs without cracks, and with high reflectivity and broad stopband.

The present inventors have made intensive study on DBRs for vertical cavity surface emitting lasers and, consequently, achieved the present invention to solve the above problems.

The present invention is directed to

1. A fabrication of group III nitride based distributed Bragg reflectors comprises

(1) a buffer layer grown on a substrate;

(2) a thick GaN layer grown on the buffer layer;

(3) one or more than one pair of a quarter-wave GaN and AlN reflector films grown on the thick GaN layer; and

(4) one or more than one pair of AlN/GaN superlattice layers (one quarter-wave), and a quarter-wave GaN layer.

2. For the fabrication of group III nitride based DBRs as described in Item 1, except for the same lattices constant of substrate such as GaN, the substrate is at least one selected from all different lattices constant materials. For example, the substrate is one of sapphire, silicon carbide (SiC), zinc oxide (ZnO) and silicon substrate.

3. Fabrication of group III nitride based DBRs as described in Item 1, a buffer layer is grown at growth temperature of 100˜1000° C.

4. Fabrication of group III nitride based DBRs as described in Item 1, a thick GaN layer is grown at growth pressure of 50˜500 Torr and ratating speed of 900 rpm.

5. Fabrication of group III nitride based DBRs as described in Item 1, the reflector films are grown at carrier gas nitrogen (N₂) flow rate of 10˜6000 sccm, hydrogen (H₂) flow rate of 0˜200 sccm, growth pressure of 1˜300 Torr, NH₃ flow rate of 100˜1500 sccm, TMGa flow rate of 1˜20 sccm, TMA1 flow rate of 10˜200 sccm and temperature of 300˜1500° C.

6. Fabrication of group III nitride based DBRs as described in Item 1, the superlattice layers are grown at same condition as the growth of DBR, but the growth time is shorter than reflector films.

7. Fabrication of group III nitride based DBRs as described in Item 1, all epilayers are grown by metalorganic chemical vapor phase epitaxy, hydride vapor phase epitaxy, molecular beam epitaxy, or hot wall epitaxy.

8. Fabrication of group III nitride based DBRs as described in Item 1, the thickness of the buffer layer is in the range of 1˜100 nm.

9. Fabrication of group III nitride based DBRs as described in Item 1, the thickness of the thick GaN layer is in the range of 10 nm˜100 μm.

10. Fabrication of group III nitride based DBRs as described in Item 1, the optical thickness of each layer of the reflector films is ¼(1±20%) wavelength, and the total thickness of a pair of AlN/GaN layers is ½ wavelength.

11. A DBR fabricated by the process as described in any of Items 1 to 10, wherein a buffer layer, a GaN layer, one or more than one pair GaN/AlN reflector films, and one or more than one pair of superlattice layers are grown on a substrate in this order; and each pair of superlattice layers consist of a set of AlN/GaN superlattices (its optical thickness is one quarter-wave), and a quarter-wave GaN layer.

12. The distributed Bragg reflector as described in Item 11, which consists of one or more than one pair of AlN/GaN superlattices.

13. The distributed Bragg reflector as described in Item 11, both sides of the superlattices are thin AlN layers.

14. The distributed Bragg reflector as described in Item 11, which consists of one or more that one pair of GaN and AlN reflector films.

The present invention is exemplified and described in detail with reference to accompany figures and actual examples as following. However, the figures and actual examples illustrated in the context are useful as the best example of the present invention and the practical application thereof, and are useful to assist those in this field to better understand the concept and utility of the present invention, rather than to limit the scope thereof. Furthermore, it is appreciated to those in this field that the other variation and modification directed to the present invention not apart from the spirit and scope thereof are covered by the present invention and attached claims.

### BRIEF DESCRIPTION OF THE FIGURES

FIG. 1 shows a schematic DBR structure of 20 pairs AlN/GaN with three AlN/GaN superlattices insertion pairs.

FIG. 2(a) shows a plane-view optical microscope image magnified 50× of distributed Bragg reflector (DBR) samples without insertion of AlN/GaN superlattices; FIG. 2(b) shows a plane-view optical microscope image magnified 50× of distributed Bragg reflector (DBR) sample with AlN/GaN superlattices.

FIG. 3 shows the AFM image of the distributed Bragg reflector (DBR) sample with insertion of AlN/GaN superlattices; it is shown no observable crack at line profile but rough surface.

FIG. 4(a) shows a TEM cross-section image of distributed Bragg reflector (DBR) sample with insertion of AlN/GaN superlattices; FIG. 4(b) shows an enlarged cross-section image of one set of superlattices.

FIG. 5 shows reflectivity spectra, wherein the solid line represents the distributed Bragg reflector samples with insertion of AlN/GaN superlattices, and the dash line represents without insertion of AlN/GaN superlattices.

### DETAILED DESCRIPTION OF THE INVENTION

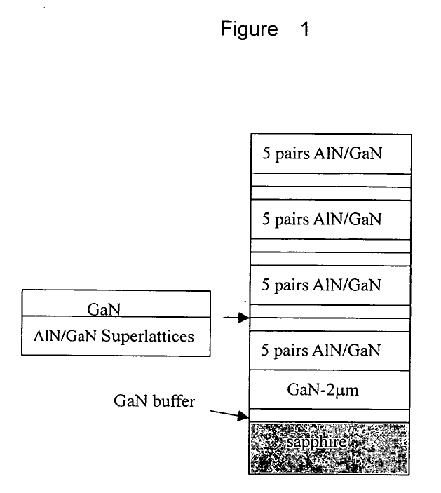

FIG. 1 shows a schematic structure of 20-pairs group III nitride based distributed Bragg reflectors. As shown in FIG. 1, the present distributed Bragg reflector at least comprises a substrate, a buffer layer, a thick GaN layer, one or more than one pair of reflector films, and one or more than one set of superlattices. The present distributed Bragg reflector is grown by metalorganic chemical vapor phase epitaxy, hydride vapor phase epitaxy, molecular beam epitaxy, or hot wall epitaxy. In comparison, another 20-pairs AlN/GaN DBR was grown without insertion of AlN/GaN superlattices when growth parameters were kept constant.

In addition, the present group III nitride based distributed Bragg reflectors comprises a GaN buffer layer grown on a sapphire substrate; then a 2˜3-μm-thick GaN layer was grown on the GaN buffer layer. One or more than one pair of AlN/GaN reflector films was grown on the GaN layer. The number of DBR pairs is limited by no observable crack. In our case cracks were observed when the number of DBR pairs is greater than 5. One or more than one pair of superlattice layers, which consists of a set of GaAlN (AlN)/GaN superlattices and a quarter-wave GaN layer, was grown. Both sides of superlattices are thin GaAlN(AlN) layers. The thickness of a set of superlattices is a quarter-wave. In addition, this set of superlattices is a strain releasing layer in DBR stucture. Then one or more than one pair of AlN/GaN reflector films is grown. These steps are repeated to obtain the reflectivity DBRs as necessary.

Further, in present group III nitride based distributed Bragg reflectors, the GaN buffer layer and a 2˜3μm-thick GaN layer may be replaced by any other group III nitride epilayer, without affecting the present invention. For example, these group III nitride epilayers are selected from any of AlN, AlGaN and GaN.

Without a particular limitation, the substrate used for the distributed Bragg reflectors in the present process may be selected from at least one of all lattice constant different from GaN materials. For example, it is one of sapphire, silicon carbide (SiC), zinc oxide (ZnO) and silicon substrate. Sapphire should be preferred.

Furthermore, the growth temperature of the buffer layer in the present invention is usually in the range of 100˜1000° C., 500° C. is preferred. Besides, the thickness of the buffer layer is not particularly limited, as long as it does not affect the quality of consequent epilayers. However, it is usually in the range of 1˜100 nm; preferably 5˜80 nm; and more preferably 15˜50 nm. The thickness of the GaN layer is usually in the range of 1˜3 μm.

Next, according to the present fabrication of distributed Bragg reflectors, it is possible to grow GaN layer with any conventional methods, e.g., metalorganic chemical vapor phase epitaxy, hydride vapor phase epitaxy, molecular beam epitaxy, or hot wall epitaxy, without particular limitation. Also, the GaN layer is usually grown at growth pressure of 50˜500 torr and rotating speed below 1000 rpm, preferably pressure of 1˜300 torr and rotating speed around 900 rpm. The thickness of the GaN layer is not particularly limited, as long as it does not affect the quality of consequent epilayers. However, it is usually in the range of 0.5˜10 μm, and preferably 3 μm.

According to the present fabrication of distributed Bragg reflectors, it is possible to grow reflector film with any conventional methods, e.g., metalorganic chemical vapor phase epitaxy, hydride vapor phase epitaxy, molecular beam epitaxy, or hot wall epitaxy, without particular limitation. Also, the reflector film is usually grown at carrier gas nitrogen (N₂) flow rate of 10˜6000 sccm and hydrogen (H₂) flow rate of 0˜500 sccm, growth pressure of 1˜300 torr, and growth temperature of 700˜1500° C.; preferably carrier gas nitrogen (N₂) flow rate of 50˜5500 sccm, hydrogen (H₂) flow rate of 0˜300 sccm, growth pressure of 10˜250 torr, and growth temperature of 800˜1300° C.; more preferably carrier gas nitrogen (N₂) flow rate of 100˜5000 sccm, hydrogen (H₂) flow rate of 0˜200 sccm, growth pressure of 50˜220 torr, and growth temperature of 900˜1100° C. Besides, the thickness of the reflector film is not particularly limited, as long as the effect of the present is not compromised. However, the thickness of either GaN or AlN is usually ¼(1±20%) wavelength ((1±20%) means that it is allowed to have a thickness variation of increasing or decreasing 0˜20%). Also, the total thickness of a pair of AlN/GaN layers is ½ wavelength. Preferably, to suppress of the generation of cracks, the thickness of GaN is 5% more than normal ¼ wavelength, and that of AlN is 5% less than normal ¼ wavelength.

Thus, a distributed Bragg reflector without cracks is achieved according to the present invention.

### EXAMPLE

The example of the present invention are described below, however, the present invention is not limited thereto.

### Example 1

### Preparation of Distributed Bragg Reflectors with Insertion of AlN/GaN Superlattices

Referring to FIG. 1, which shows the present process, distributed Bragg reflectors with insertion of AlN/GaN supperlattices were grown by metalorganic chemical vapor phase epitaxy.

First, an epi-ready sapphire substrate was placed into MOCVD reactor chamber. The impurities on the surface of the substrate were removed in high temperature (1100° C.) hydrogen atmosphere for 5 minutes, and then growth temperature was reduced to 500° C. to grow a buffer layer of 30-nm-thick. Next, a GaN layer of 3-μm-thick was grown on the buffer layer at the growth pressure of 200 torr and rotating speed of 900 rpm.

Subsequently, the DBR structures were grown in nitrogen with hydrogen ambient. The carrier gas flow rate (H₂/N₂) was 4200/100 sccm, growth pressure was 100 torr, and growth temperature was 1100° C. The growth time was controlled according to the growth rate measured by filmtrics, to ensure each layer was of a thickness of ¼ wavelength. Preferably, to facilitate the suppression of the generation of cracks, the thickness of GaN was 5% more than normal ¼ wavelength, and that of AlN was 5% less than normal ¼ wavelength.

| | | Pressure | NH₃ Flow | TMGa Flow | TMA1 Flow |
|---|---|---|---|---|---|
| | | (Torr) | Rate (sccm) | Rate (sccm) | Rate (sccm) |
| GaN | 1100 | 100 | 900 | 12 | |
| AlN | 1100 | 100 | 900 | | 80 |

The growth condition of reflector films was shown above. NH₃ flow rate was 0-7000 sccm, TMGa flow rate was 12 sccm (with source temperature of −5° C.), and TMA1 flow rate was 80 sccm (with source temperature of 10° C.). The flow rate was dependent on source temperature. Totally 5 pairs of AlN/GaN reflector films were grown. Additionally, a pair of superlattice layers was grown. The growth condition was the same as that of reflector films. Each pair of superlattice layers consisted of a set of superlattices (the thickness is one quarter-wave) and a quarter-wave GaN layer. The growth condition was the same as shown above. Each set of superlattices consisted of 5.5 layers of AlN and GaN, wherein the GaN/AlN superlattices insertion layers were ended by one more AlN layer to identify the interface changing from the AlN layer to the GaN layer. The thickness of each layer in superlattices insertion was controlled about 3˜5 nm by growth time.

Thereafter, the obtained distributed Bragg reflector (DBR) samples with insertion of AlN/GaN superlattices were observed with optical microscopy and AFM to confirm the presence of crack. The thicknesses of the individual layers in the DBR with insertion of AlN/GaN superlattices were investigated by transmission electronic microscope (TEM). The reflection property was evaluated with n&k ultraviolet-visible spectrometer with normal incidence at room temperature.

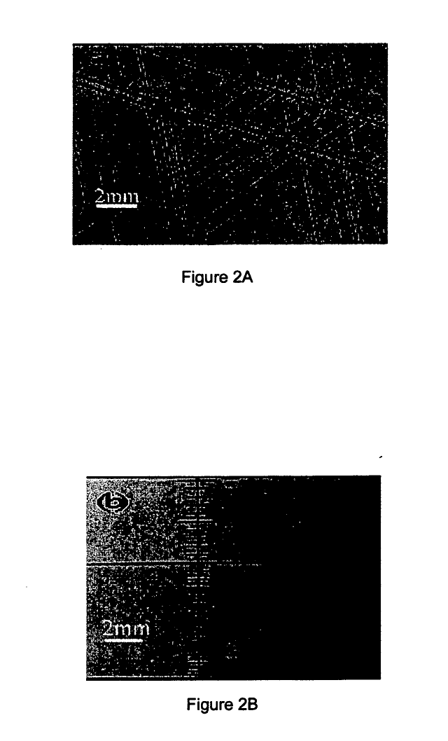

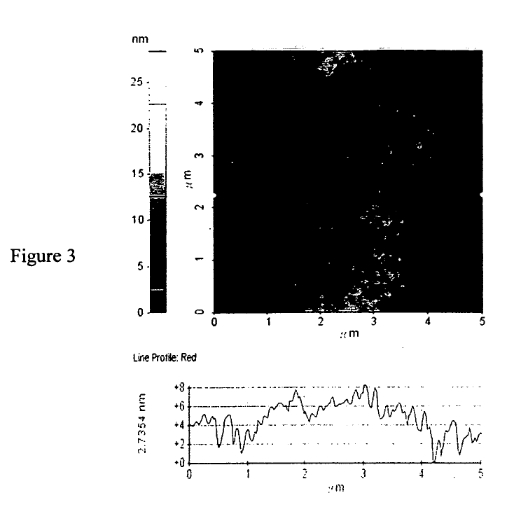

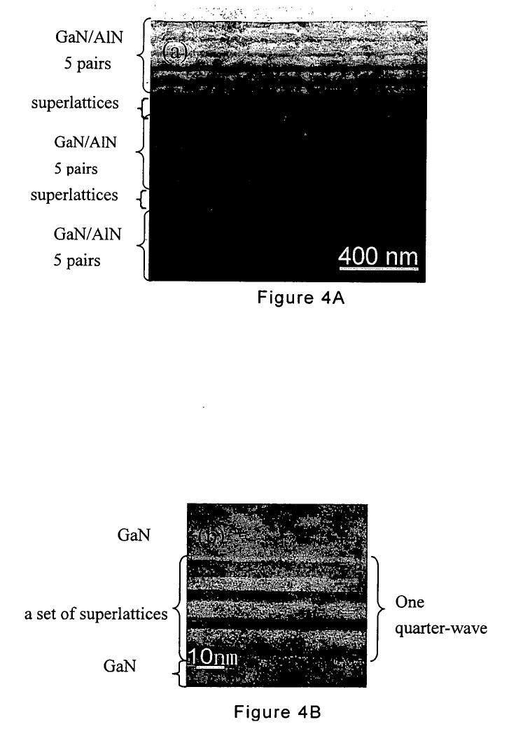

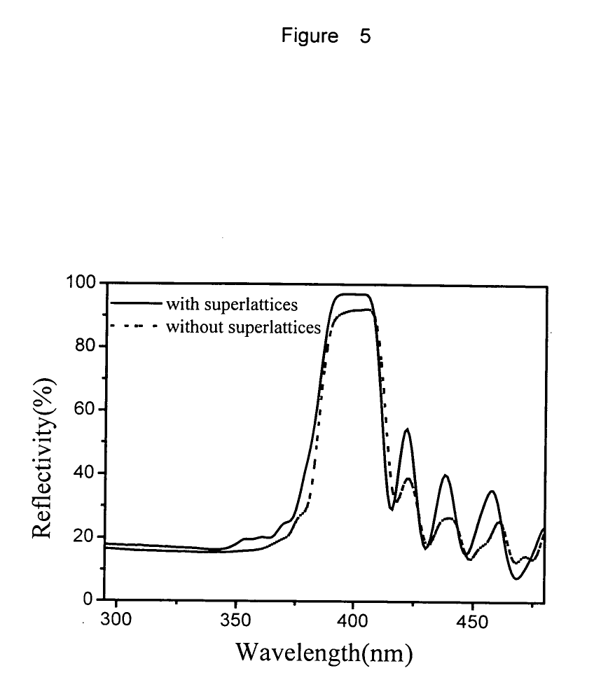

FIG. 2 (b) shows the optical microscopy image magnified 50× of DBR with insertion of AlN/GaN superlattices. The cracks were not observed on the surfaces of DBR samples with insertion of AlN/GaN superlattices. The surface of DBR samples with insertion of AlN/GaN superlattices also was measured by atomic force mircroscopy (AFM) shown in FIG. 3 and line profile shows crack free. FIGS. 4 (a) and (b) show cross sectional TEM image of DBR samples with insertion of AlN/GaN superlattices. The lighter layers represent AlN layers while the darker layers represent GaN layers. In FIG. 4(a), no cracks can be observed in the TEM image. The solid line in FIG. 5 represents the reflectivity spectrum of DBR samples with insertion of AlN/GaN superlattices, while the dash line represents DBR samples without insertion of AlN/GaN superlattices. It can be seen that DBR sample with insertion of AlN/GaN superlattices with a peak reflectivity up to 97% at central wavelength of 399 nm, and the width of stopband up to 14 nm. In contrast, the peak reflectivity of the DBR sample without insertion of AlN/GaN superlattices was 92%, as the presence of cracks mainly reduces reflectivity.

### Comparative Example 1

The another actual example without insertion of AlN/GaN superlattices were grown at same growth parameters. As a result, cracks were observed on the surface of 20 pairs of DBR sample without insertion of AlN/GaN superlattices as shown in FIG. 2(a). Its reflectivity spectrum was shown in FIG. 5 in the dash line.

Form the comparison between the results of Example and Comparative Example, it is known that no crack on the surfaces of the present Example with insertion of AlN/GaN superlattices, and instead, cracks on the surface of Comparative Example without insertion of AlN/GaN superlattices.

Further, the insertion of AlN/GaN superlattics may improve the reflectivity on the surface. For example, the reflectivity of DBR with insertion of AlN/GaN superlattices is 97%, much higher than those of Comparative Example without insertion of AlN/GaN superlattices (only 92%).

### INDUSTRY APPLICABILITY

According to the present invention, to insert AlGaN/AlN, GaAlN/GaN and AlN/GaN layers by metalorganic chemical vapor phase epitaxy into AlN/GaN reflectors, it is possible to suppress strain so that no observable cracks are on the surface of reflector, and the surface roughness is reduced to 2.5 nm. The peak reflectivity at central wavelength of 399 nm increases from 92% to 97%.

Accordingly, the present invention solves the existing problems in distributed Bragg reflectors (DBR) used in the prior art, and further provides a fabrication method of DBR for vertical cavity surface emitting lasers (VCSELs). This technique should be applicable for the fabrication of group III nitride based VCSELs required high reflectivity and broad stopband width group III nitride based DBRs.

1. A process for fabricating group III nitride based distributed Bragg reflectors comprising:
(1) step of growing a buffer layer on a substrate;
(2) step of growing a GaN layer on the buffer layer;
(3) step of growing one or more pair(s) of GaN and AlN reflector films on the GaN layer; and
(4) step of growing one or more pair(s) of superlattice layers, wherein each pair of superlattice layers consist of a set of superlattice made of more than one layer of GaN and AlN, and a GaN layer.

2. The process for fabricating group III nitride based distributed Bragg reflectors as described in claim 1, wherein the substrate is at least one selected from sapphire, silicon carbide (SiC), zinc oxide (ZnO), silicon substrate, and the combination thereof.

3. The process for fabricating group III nitride based distributed Bragg reflectors as described in claim 1, wherein the buffer layer is grown at temperature of 100˜1000° C.

4. The process for fabricating group III nitride based distributed Bragg reflectors as described in claim 1, wherein the GaN layer is grown at pressure of 50˜500 torr and rotating speed of 900 rpm.

5. The process for fabricating group III nitride based distributed Bragg reflectors as described in claim 1, wherein the reflector films are grown under carrier gas nitrogen (N₂) flow rate of 10˜6000 sccm, hydrogen (H₂) flow rate of 0˜200 sccm, pressure of 1˜300 torr, and temperature of 300˜1500° C.

6. The process for fabricating group III nitride based distributed Bragg reflectors as described in claim 1, wherein the superlattice layers are grown at condition of NH₃ flux of 100˜1500 sccm, TMGa flux of 1˜20 sccm, and TMA1 flux of 10˜200 sccm.

7. The process for fabricating group III nitride based distributed Bragg reflectors as described in claim 1, wherein the GaN layer is grown with metalorganic chemical vapor phase epitaxy, hydride vapor phase epitaxy, molecular beam epitaxy, or hot wall epitaxy.

8. The process for fabricating group III nitride based distributed Bragg reflectors as described in claim 1, wherein the thickness of the buffer layer is in the range of 1˜100 nm.

9. The process for fabricating group III nitride based distributed Bragg reflectors as described in claim 1, wherein the thickness of the GaN layer is in the range of 10˜100 nm.

10. The process for fabricating group III nitride based distributed Bragg reflectors as described in claim 1, wherein the optical thickness of each layer of the reflector films is ¼(1±20%) wavelength, and the total thickness of a pair of AlN/GaN layers is ½ wavelength.

11. A distributed Bragg reflector fabricated by the process as described in claim 1, wherein a buffer layer, a GaN layer, a pair of or more reflector films made of GaN/AlN, and a pair of or more superlattice layers are grown on a substrate in this order; and wherein each pair of superlattice layers consist of a set of superlattice made of more than one layer of GaN/AlN, and inserted with a GaN layer; the thickness of a set of superlattices is one quarter-wave.

12. The distributed Bragg reflector as described in claim 11, which consists of at least one or more pair(s) of superlattice layers.

13. The distributed Bragg reflector as described in claim 11, wherein both sides of the superlattice are thin AlN layers.

14. The distributed Bragg reflector as described in claim 11, which consists of at least one or more pair(s) of reflector films made of GaN and AlN.
